(19) United States
(12) Patent Application Publication
(10) Pub. No.: US 2026/0305112 A1
(43) Pub. Date: Oct. 1, 2026

(54) DISPLAY DEVICE

(71) Applicant: LG Display Co., Ltd., Seoul (KR)

(72) Inventors: Sangsu JANG, Paju-si (KR); Seungyong NAM, Paju-si (KR); Taeyoung OH, Paju-si (KR); Seunghyun LEE, Paju-si (KR)

(73) Assignee: LG Display Co., Ltd., Seoul (KR)

(21) Appl. No.: 19/633,677

(22) Filed: Mar. 30, 2026

(30) Foreign Application Priority Data
Mar. 31, 2025 (KR) 10-2025-0041277

(51) Int. Cl. H10K 59/38; H10K 59/40

(52) U.S. Cl. CPC H10K 59/38; H10K 59/40

(57) ABSTRACT

A display device can include a display area having first to third emitting areas configured to emit light of first to third colors, respectively, and a non-emitting area surrounding each of the first, second and third emitting areas. The display device can also include a non-display area disposed around the display area, a first color filter disposed in the first emitting area, the non-emitting area, and the non-display area, a second color filter disposed in the second emitting area, a third color filter disposed in the third emitting area, the non-emitting area, and the non-display area. Additionally, the display device can include a touch electrode disposed in the non-emitting area, and the touch electrode can include a first layer comprising a first material, a second layer disposed on the first layer, and a third layer disposed on the second layer .

### CROSS-REFERENCE TO RELATED APPLICATIONS

This application claims priority to and the benefit of Korean Patent Application No. 10-2025-0041277, filed in the Republic of Korea on Mar. 31, 2025, the disclosure of which is hereby expressly incorporated by reference in its entirety.

### BACKGROUND

### Technical Field

Embodiments of the present disclosure relate to a display device.

### Discussion of the Related Art

With advancement of the information society demand for diverse display devices have increased. Accordingly, various types of display devices, such as liquid crystal displays and organic light emitting diode displays, are being developed and used.

These display device can display a wide range of content in the form of a still image or a moving image, and in the case of a moving image, the display device can display a sports image, a game image, a movie, etc. The display device can include a plurality of pixels and a plurality of switching elements for driving the pixels to provide the various images.

### SUMMARY OF THE DISCLOSURE

Accordingly, one object of embodiments of the present disclosure is to solve or address the above-noted disadvantages of the prior art, and embodiments of the present disclosure can provide a display device that can improve the visibility of touch electrodes and touch lines

Aspects according to the present disclosure are not limited to the above ones, and other aspects and advantages that are not mentioned above can be clearly understood from the following description and can be more clearly understood from the embodiments set forth herein.

To accomplish the objects of the present disclosure, a display device can include a display area including first to third emitting areas configured to emit light of first to third colors, respectively, and non-emitting areas surrounding each of the first to third emitting areas; a non-display area disposed around the display area; a first color filter disposed in the first emitting area, the non-emitting area, and the non-display area; a second color filter disposed in the second emitting area; a third color filter disposed in the third emitting area, the non-emitting area, and the non-display area; and a touch electrode disposed in the non-emitting area, and the touch electrode can include a first layer including a first material; a second layer disposed on the first layer; and a third layer disposed on the second layer and including a second material having a lower reflectivity than the first material.

In another aspect, a display device according to another embodiment according to the present disclosure can include a display area including first to third emitting areas configured to emit light of first to third colors, respectively, and non-emitting areas surrounding each of the first to third emitting areas; a non-display area disposed around the display area; a touch electrode disposed in the non-emitting area; a touch line disposed in the non-display area and electrically connected to the touch electrode; a first color filter disposed in the first emitting area, the non-emitting area, and the non-display area, to overlap the touch electrode and the touch line; a second color filter disposed in the second emitting area; and a third color filter disposed in the third emitting area, the non-emitting area, and the non-display area, to overlap the touch electrode and the touch line.

Specific descriptions of other embodiments according to the present disclosure are provided in detailed description and the accompanying drawings.

According to the embodiments of the present disclosure, the display device can prevent the recognition of touch electrodes and touch lines without including a separate black matrix by including first and third color filters arranged in a non-luminous area and a non-display area.

The display device according to the embodiments of the present disclosure can reduce the number of manufacturing processes and reduce manufacturing costs by not including a separate black matrix.

In addition to the above-described effects, specific effects of the present invention will be described together with the following detailed description for implementing the present invention.

### BRIEF DESCRIPTION OF THE DRAWINGS

FIG. 1 is a plan view illustrating a display device according to one embodiment according to the present disclosure;

FIG. 2 is a cross-sectional view illustrating a display device according to an embodiment according to the present disclosure;

FIG. 3 is a block diagram illustrating a display device according to an embodiment according to the present disclosure;

FIG. 4 is a plan view illustrating first to third color filters in a display device according to an embodiment according to the present disclosure;

FIG. 5 is a plan view illustrating a first color filter in a display device according to an embodiment according to the present disclosure;

FIG. 6 is a plan view illustrating a second color filter in a display device according to an embodiment according to the present disclosure;

FIG. 7 is a plan view illustrating a third color filter in a display device according to an embodiment according to the present disclosure;

FIG. 8 is a cross-sectional view cut along line I-I’ of FIG. 4;

FIG. 9 is a cross-sectional view cut along line II-II' of FIG. 4;

FIG. 10 is a cross-sectional view cut along line III-III' of FIG;

FIG. 11 is a cross-sectional view cut along line IV-IV' of FIG. 4;

FIG. 12 is a graph showing reflectance based on the thickness of a low-reflection metal in a display device according to one embodiment according to the present disclosure;

FIG. 13 is a graph showing visibility based on the wavelength of a low-reflection metal overlapping the first and third color filters in a display device according to one embodiment according to the present disclosure;

FIG. 14 is a graph showing absorption coefficients according to the wavelength of each of a black matrix and the first and third color filters in a display device according to one embodiment according to the present disclosure; and

FIG. 15 is a graph showing visibility according to the wavelength by combining a color filter, a black matrix, and a low-reflection metal in a display device according to one embodiment according to the present disclosure.

### DETAILED DESCRIPTION OF THE EMBODIMENTS

Hereinafter, description will now be given in detail according to example embodiments according to the present disclosure disclosed herein, with reference to the accompanying drawings. In the present disclosure, when a component (or region, layer, portion, etc.) is said to be “on,” “connected,” or “coupled” to another component, it means that it can be directly connected/coupled to the other component, or a third component can be arranged between them.

Below, example embodiments according to the disclosure are specifically described with reference to the accompanying drawings. In the drawings, identical reference numerals can denote identical or similar components. The thicknesses, proportions, and dimensions of the components are exaggerated for the purpose of effectively illustrating the technical content. "And/or" includes all combinations of one or more of the associated components that can be defined.

It will be understood that the terms such as “first” and “second” are used herein to describe various components but these components should not be limited by these terms. The above terms are used only to distinguish one component from another. For example, a first component can be referred to as a second component and vice versa without departing from the scope of the invention. The singular expressions include plural expressions unless the context clearly dictates otherwise.

Terminologies such as “under,” “below,” “on,” “above,” and etc. are used to describe location relationship between the elements shown in the drawings. Such terminologies are relative concepts and described with respect to directions shown in the accompanying drawings.

Throughout the disclosure, each component can be provided as a single one or a plurality of ones, unless explicitly stated to the contrary. Terms such as “include” or “comprise” are used herein and should be understood that they are intended to indicate an existence of several components, functions or steps, disclosed in the disclosure, and it is also understood that greater or fewer components, functions, or steps can likewise be utilized. A singular representation can include a plural representation unless it represents a definitely different meaning from the context. In understanding the components, it should be understood as including the error range even if there is no separate explicit description. Further, the term “can” fully encompasses all the meanings and coverages of the term “may” and vice versa.

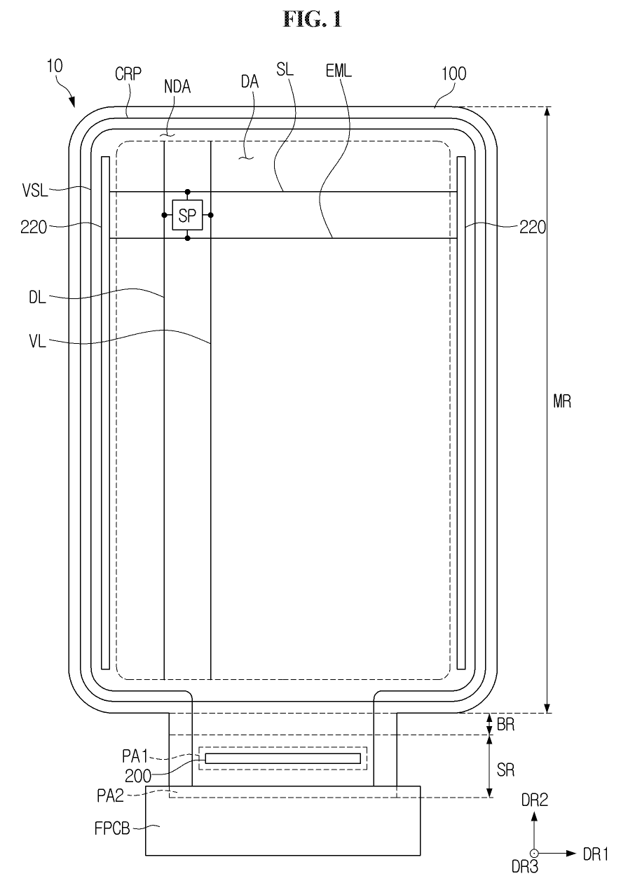

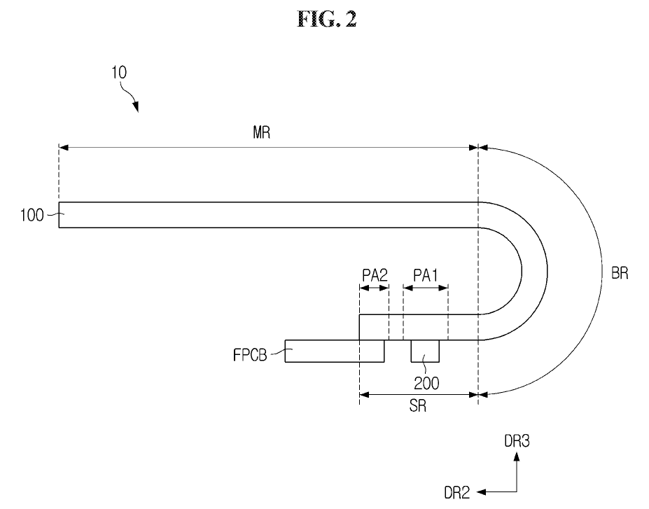

FIG. 1 is a plan view illustrating a display device according to one embodiment. FIG. 2 is a cross-sectional view illustrating a display device according to an embodiment according to the present disclosure. All components of each display device according to all embodiments of the present disclosure are operatively coupled and configured.

Referring to FIG. 1, the display device 10 can be applied to portable electronic devices such as mobile phones, smart phones, tablet personal computers (PCs), mobile communication terminals, electronic notebooks, electronic books, portable multimedia players (PMPs), navigation systems, and ultra-mobile PCs (UMPCs). As another example, the display device 10 can be applied to wearable devices such as a smart watch, a watch phone, a glasses-type display, and a head-mounted display (HMD). As a further example, the display device 10 can be applied to a television, a laptop, a monitor, a billboard, or a display unit of the Internet of Things (IoT). The embodiments according to the present disclosure are not limited thereto.

The display device 10 can include a display panel 100, a display driver 200, and a scan driver 220. The scan driver 220 can be a gate-in panel (GIP). The display panel 100 can include a main region (MR), a sub-region (SR), and a bending region (BR) between the main region (MR) and the sub-region (SR). The embodiments according to the present disclosure are not limited thereto.

The main region (MR) can include a display area (DA) and a non-display area (NDA). The planar shape of the display area (DA) can have a rectangular shape. In other examples, the planar shape of the display area (DA) can be a square, circular, oval, or other polygonal shape. For example, the display area (DA) can be a rectangular shape with rounded corners, but the embodiments according to the present disclosure are not limited thereto, and it can also be a rectangular shape with sharp corners. The embodiments according to the present disclosure are not limited thereto.

The first direction (DR1) and the second direction (DR2) can intersect vertically on a plan view, and the third direction (DR3) can intersect a plane including the first and second directions (DR1, DR2). Hereinafter, the first direction (DR1) corresponds to the right, the direction opposite to the first direction (DR1) corresponds to the left, the second direction (DR2) corresponds to the upper side, and the direction opposite to the second direction (DR2) corresponds to the lower side. However, the arrangement relationship between components is not limited to the direction.

The display area (DA) can include a plurality of pixels (SP) that display an image. The pixels (SP) can emit light through an emitting area or an aperture area. The pixels (SP) can include a pixel circuit including switching elements, a pixel defining film defining an emitting area, and a self-light emitting element. For example, the self-luminous element can include, but is not limited to, at least one of an organic light emitting diode (OLED) including an organic light emitting layer, a quantum dot LED including a quantum dot light emitting layer, an inorganic LED including an inorganic semiconductor, and an ultra-small light emitting diode (micro LED or nano LED).

The display area (DA) can include short sides extending along a first direction (DR1) and long sides extending along a second direction (DR2). A non-display area (NDA) can be arranged around the display area (DA). The non-display area (NDA) can include a first side arranged in the first direction (DR1), a second side arranged in a direction opposite to the first direction (DR1), a third side arranged in the second direction (DR2), and a fourth side arranged in a direction opposite to the second direction (DR2). Here, the first side of the non-display area (NDA) can be the right side, the second side can be the left side, the third side can be the upper side, and the fourth side can be the lower side.

The display device 10 may include scan lines (SL). The scan lines (SL) can extend in the first direction (DR1) and can be spaced apart from each other in the second direction (DR2). Scan lines (SL) can sequentially supply scan signals to a plurality of pixels (SP). The scan lines (SL) can be gate lines or gate lines.

The display device 10 may include light-emission control lines (EML). The light-emission control lines (EML) can extend in a first direction (DR1) and can be spaced apart from each other in a second direction (DR2). The light-emission control lines (EML) can sequentially supply light-emission signals to a plurality of pixels (SP).

The display device 10 may include data lines (DL). The data lines (DL) can extend in a second direction (DR2) and can be spaced apart from each other in a first direction (DR1). The data lines (DL) can supply data voltages to the pixels (SP). The data voltages can determine the luminance of each pixel (SP).

The display device 10 may include power lines (VL). The power lines (VL) can extend in a second direction (DR2) and can be spaced apart from each other in a first direction (DR1). Power lines (VL) can supply power voltages to pixels (SP). Here, the power voltages can include, but are not limited to, a driving voltage, a low-potential voltage, an initialization voltage, a reference voltage, and a bias voltage.

A scan driver 220 can be disposed on each of the first and second sides of the non-display area (NDA). The scan driver 220 can include a plurality of transistors and supply scan signals to a plurality of pixels (SP). The scan signals of the scan driver 220 can select pixels (SP) to which data voltages are supplied, and the selected pixels (SP) can receive the data voltages through data lines. The scan driver 220 can be disposed in the non-display area (NDA) in a Gate In Panel (GIP) manner.

A low-potential line (VSL) can be disposed in the non-display area (NDA) and surround the scan driver 220 and the display area (DA). For example, a low-potential line (VSL) can extend from a flexible film (FPCB), pass through a sub-region (SR) and a bending region (BR), and be arranged on the first to fourth sides of a non-display area (NDA) to surround the scan driver 220 and the display area (DA). The embodiments according to the present disclosure are not limited thereto.

The bending region (BR) and the sub-region (SR) can extend from the lower side of the main region (MR). The bending region (BR) can be positioned between the sub-region (SR) and the main region (MR). In FIG. 2 , the bending region (BR) can be bent based on a bending axis in the first direction (DR1), and the main region (MR) and the sub-region (SR) can overlap in the thickness direction or the third direction (DR3). The display panel 100 can be bent such that the lower surface of the main region (MR) and the upper surface of the sub-region (SR) face each other.

The sub-region (SR) can include a first pad region (PA1) and a second pad region (PA2). The first pad region (PA1) can be positioned in the central portion of the sub-region (SR) to mount the display driver 200. The first pad area (PA1) can include a plurality of pad portions and be electrically connected to the display driver 200. The display driver 200 can supply a data voltage to a data line of the display panel 100). The display driver 200 can be formed as an integrated circuit (IC). For example, the display driver 200 can be arranged in the first pad area (PA1) in a chip-on-plastic (COP) or chip-on-glass (COP) manner. As another example, the display driver 200 can be arranged in a chip-on-film (COP) manner. The display driver 200 can be a data driver. The embodiments according to the present disclosure are not limited thereto.

The second pad area (PA2) can be arranged at the lower edge of the sub-area (SR). The second pad area (PA2) can include a plurality of pad portions and be electrically connected to a flexible film (FPCB). For example, a flexible film (FPCB) can electrically connect a timing control unit, a power supply unit, and a memory to the display panel 100.

A crack detection pattern (CRP) can surround the low-voltage line (VSL), the scan driver (220), and the display area (DA). The crack detection pattern (CRP) can be arranged on the first to fourth sides of the non-display area (NDA) to completely surround the display area (DA). In another example, the crack detection pattern (CRP) can be not arranged on a portion of the non-display area (NDA). If an external impact is applied to the display device (10), the crack detection pattern (CRP) can be damaged, and a damaged crack detection pattern (CRP) can indicate that a crack has occurred in the display device 10.

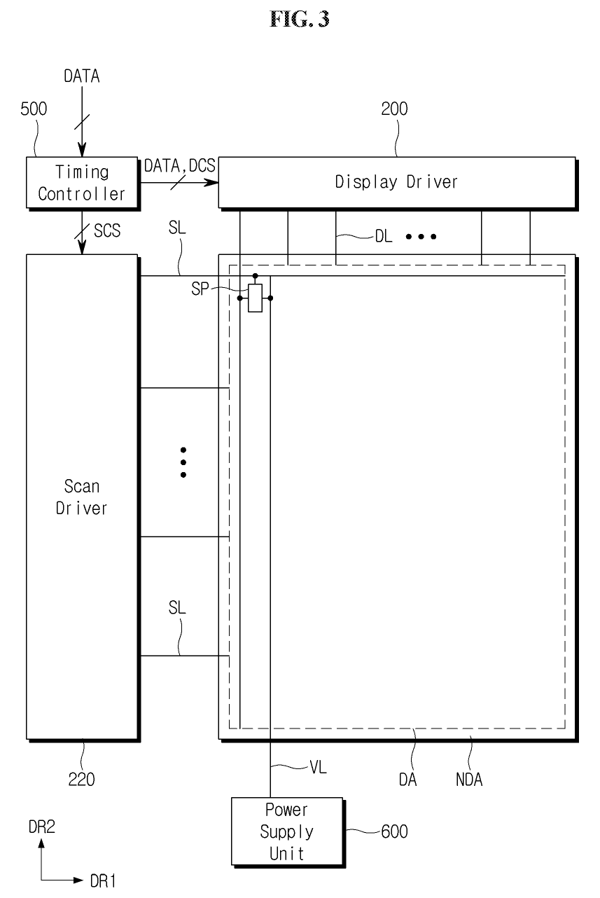

FIG. 3 is a block diagram illustrating a display device according to one embodiment according to the present disclosure.

Referring to FIG. 3, the display panel 100 can include a display area (DA) and a non-display area (NDA). The display area (DA) can include a plurality of pixels (SP), a power line (VL), a scan line (SL), and a data line (DL) connected to the pixels (SP).

Each of the plurality of pixels (SP) can be connected to the scan line (SL), the data line (DL), and the power line (VL). Each of the plurality of pixels (SP) can include a transistor, a light-emitting element, and a capacitor.

Scan lines (SL) can extend in the first direction (DR1) and can be spaced apart from each other in the second direction (DR2) intersecting the first direction (DR1). The scan lines (SL) can sequentially supply scan signals to the plurality of pixels (SP).

Data lines (DL) can extend in the second direction (DR2) and can be spaced apart from each other in the first direction (DR1). The data lines (DL) can supply data voltages to the pixels (SP). The data voltages can determine the luminance of the pixels (SP).

Power lines (VL) can extend in the second direction (DR2) and can be spaced apart from each other in the first direction (DR1). The power lines (VL) can supply power voltages to the plurality of pixels (SP). The power voltages can include, but are not limited to, a driving voltage, a low-potential voltage, an initialization voltage, a reference voltage, and a bias voltage.

The scan driver 220 can include a plurality of transistors and generate scan signals based on a scan control signal (SCS). The scan driver 220 can shift the scan signals using a shift register and sequentially supply the shifted scan signals to the scan lines (SL). The scan signals of the scan driver 220 can select pixels (SP) to which data voltages are supplied, and the selected pixels (SP) can receive the data voltages through data lines (DL). The scan driver 220 can be arranged on one or both sides of the non-display area (NDA) in a GIP (Gate In Panel) manner.

The display panel 100 may include a timing control unit 500. The timing control unit 500 can receive digital video data (DATA) and a timing signal from a graphic device or a set module. The timing control unit 500 can generate a data control signal (DCS) based on the timing signal. The timing control unit 500 can control the operation timing of the display driver 200 by supplying digital video data (DATA) and a data control signal (DCS) to the display driver 200. The display driver 200 can convert the digital video data (DATA) into analog data voltages and supply them to the data lines (DL). The timing control unit 500 can generate a scan control signal (SCS) based on the timing signal. The timing control unit 500 can control the operation timing of the scan driver 220 by supplying the scan control signal (SCS) to the scan driver 220. The timing control unit 500 can vary the operation frequency of the display panel 100 based on the input frequency received from the graphic device.

The display panel 100 may include a power supply unit 600. The power supply unit 600 can supply a power voltage to the power line (VL). The power supply voltage can include, but is not limited to, a driving voltage, a low-potential voltage, an initialization voltage, a reference voltage, and a bias voltage. The power supply unit 600 can generate a driving voltage and supply it to a driving voltage line, generate an initialization voltage and supply it to an initialization voltage line, generate a bias voltage and supply it to a bias voltage line, generate a reference voltage and supply it to a reference voltage line, and generate a low-potential voltage and supply it to a low-potential line (VSL).

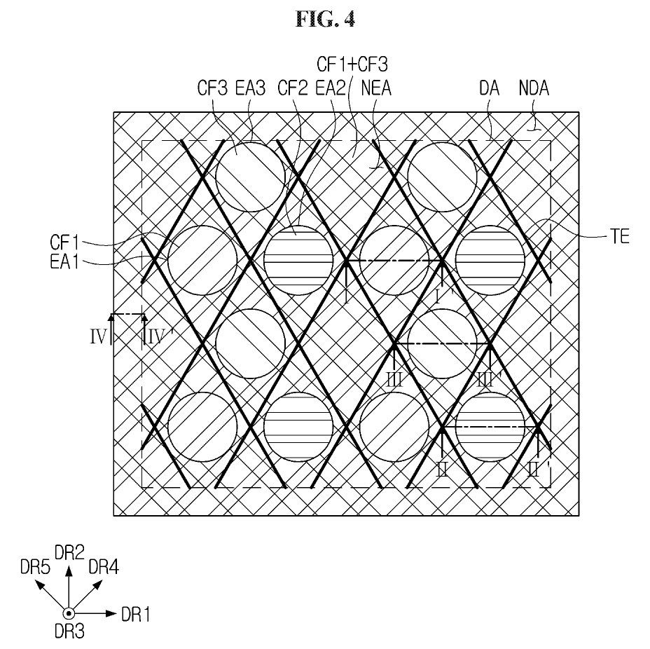

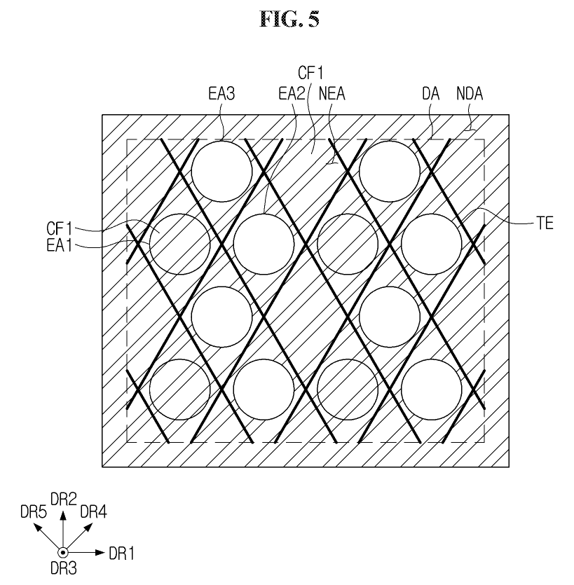

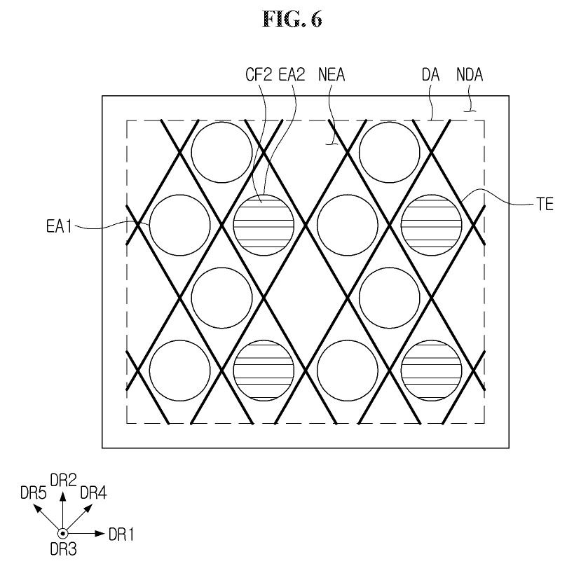

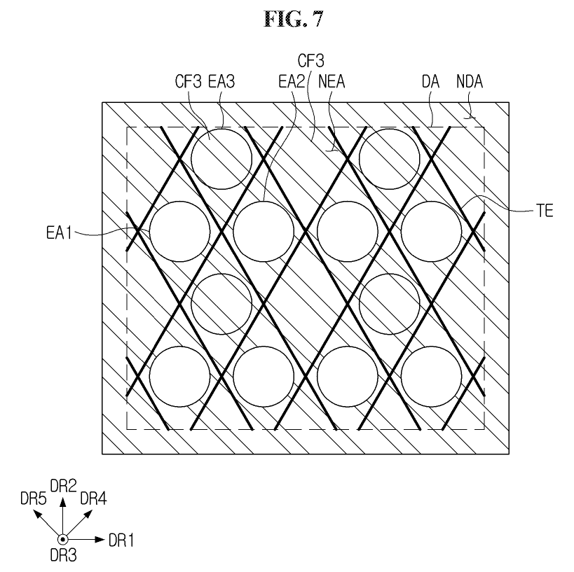

FIG. 4 is a plan view illustrating first to third color filters in a display device according to one embodiment according to the present disclosure, and FIG. 5 is a plan view illustrating the first color filter in a display device according to one embodiment according to the present disclosure. FIG. 6 is a plan view illustrating the second color filter in a display device according to one embodiment according to the present disclosure, and FIG. 7 is a plan view illustrating the third color filter in a display device according to one embodiment according to the present disclosure.

Referring to FIGS. 4 to 7, the display area (DA) can include first to third emitting areas (EA1, EA2, EA3) and a non-emitting area (NEA). The first to third emitting areas (EA1, EA2, EA3) can emit light from light-emitting elements. The light-emitting elements can be not arranged in the non-emitting area (NEA), and the non-emitting area (NEA) need not emit light. The non-emitting area (NEA) can include touch electrodes (TE) spaced apart from at least one emitting area (EA). For example, the first emitting area (EA1) can emit light of a first color or red light, the second emitting area (EA2) can emit light of a second color or green light, and the third emitting area (EA3) can emit light of a third color or blue light, but is not limited thereto. The first and second emitting areas (EA1, EA2) can be adjacent in a first direction (DR1), the first and third emitting areas (EA1, EA3) can be adjacent in a fourth direction (DR4), and the second and third emitting areas (EA2, EA3) can be adjacent in a fifth direction (DR5), but the arrangement of the first to third emitting areas (EA1, EA2, EA3) is not limited thereto.

One unit pixel can include one each of the first to third emitting areas (EA1, EA2, EA3) to express white gradation, but the configuration of the unit pixel is not limited thereto. The white gradation can be expressed by a combination of light emitted from each of the first to third emitting areas (EA1, EA2, and EA3). For another example, a unit pixel can include at least one of the first to third emitting areas (EA1, EA2, and EA3) in multiples.

The areas of the first to third emitting areas (EA1, EA2, and EA3) can be substantially the same. For another example, the areas of the first to third emitting areas (EA1, EA2, and EA3) can differ from each other. The area of the third emitting area (EA3) can be larger than the area of the first emitting area (EA1), and the area of the first emitting area (EA1) can be larger than the area of the second emitting area (EA2), but is not limited thereto.

The touch electrode (TE) can be arranged in the non-emitting area (NEA) of the display area (DA). The touch electrode (TE) can have a mesh structure or a lattice structure. The touch electrode (TE) can include a plurality of first portions extending in a fourth direction (DR4) and a plurality of second portions extending in a fifth direction (DR5). The touch electrode (TE) can surround each of the first to third emitting areas (EA1, EA2, EA3). The touch electrode (TE) can be disposed between adjacent emitting areas among the first to third emitting areas (EA1, EA2, EA3). The touch electrode (TE) can be electrically connected to the display driver 200 via a touch line disposed in the non-display area (NDA).

In FIGS. 4 and 5, the first color filter (CF1) can be disposed in the first emitting area (EA1), the non-emitting area (NEA), and the non-display area (NDA). The first color filter (CF1) can selectively transmit light of a first color (e.g., red light) and block or absorb light of a second color (e.g., green light) and light of a third color (e.g., blue light). For example, the first color filter (CF1) can be a red color filter and can include a red colorant. The first color filter (CF1) can overlap the touch electrode (TE).

In FIGS. 4 and 6 , the second color filter (CF2) can be disposed in the second emission area (EA2). The second color filter (CF2) can selectively transmit light of a second color (e.g., green light) and block or absorb light of a first color (e.g., red light) and light of a third color (e.g., blue light). For example, the second color filter (CF2) can be a green color filter and can include a green colorant. According to the various embodiments of the present disclosure, the second color filter (CF2) need not be disposed in the non-emitting area and the non-display area, but the embodiments according to the present disclosure are not limited thereto.

In FIGS. 4 and 7, the third color filter (CF3) can be disposed in the third emission area (EA3), the non-emission area (NEA), and the non-display area (NDA). The third color filter (CF3) can selectively transmit light of a third color (e.g., blue light) and block or absorb light of a first color (e.g., red light) and light of a second color (e.g., green light). For example, the third color filter (CF3) can be a blue color filter and can include a blue colorant. The third color filter (CF3) can overlap the touch electrode (TE).

Accordingly, the first and third color filters (CF1, CF3) can be arranged in the non-emission area (NEA) to overlap the touch electrode (TE) and can be arranged in the non-display area (NDA) to overlap the touch line. The display device 10 can include the first and third color filters (CF1, CF3) arranged in the non-emission area (NEA) and the non-display area (NDA), thereby preventing the touch electrode (TE) and the touch line from being viewed without including a separate black matrix. In addition, the display device 10 can reduce the number of manufacturing processes and reduce manufacturing costs by not including a separate black matrix. According to the various embodiments of the present disclosure, the second color filter (CF2) need not overlap the first and third color filters (CF1, CF3) that overlap each other in at least one of the non-emitting area (NEA) and the non-display area (NDA).

The first to third color filters (CF1, CF2, CF3) can absorb a portion of the light entering from the outside of the display device 10 to reduce light reflection due to external light. Therefore, the first to third color filters (CF1, CF2, CF3) can prevent color distortion due to external light reflection. The embodiments according to the present disclosure are not limited to first to third color filters (CF1, CF2, CF3) corresponding to red, green and blue colors, but can include additional color filters and additional or different colors.

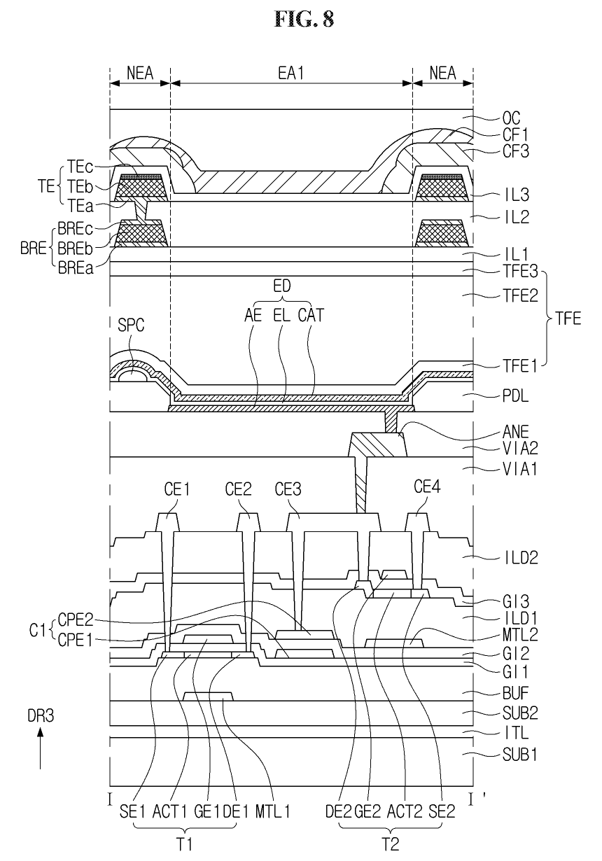

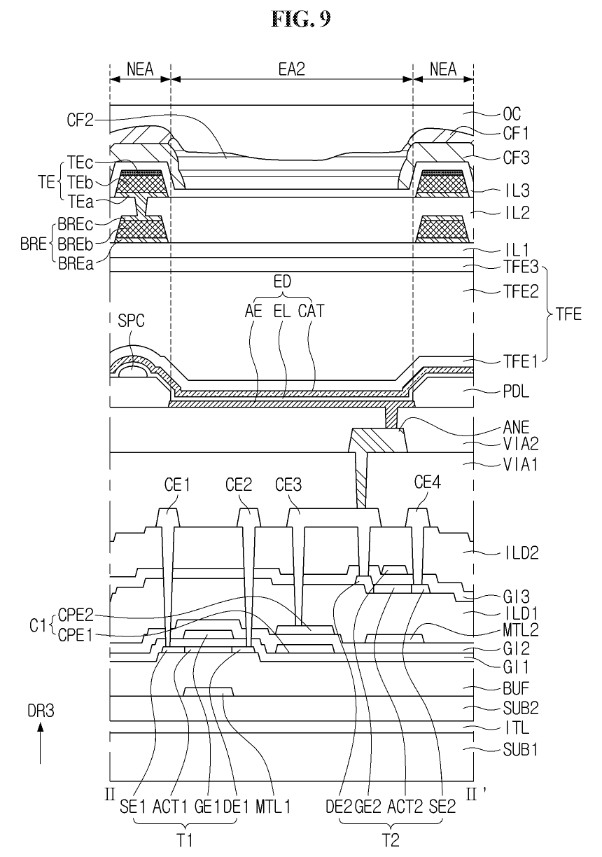

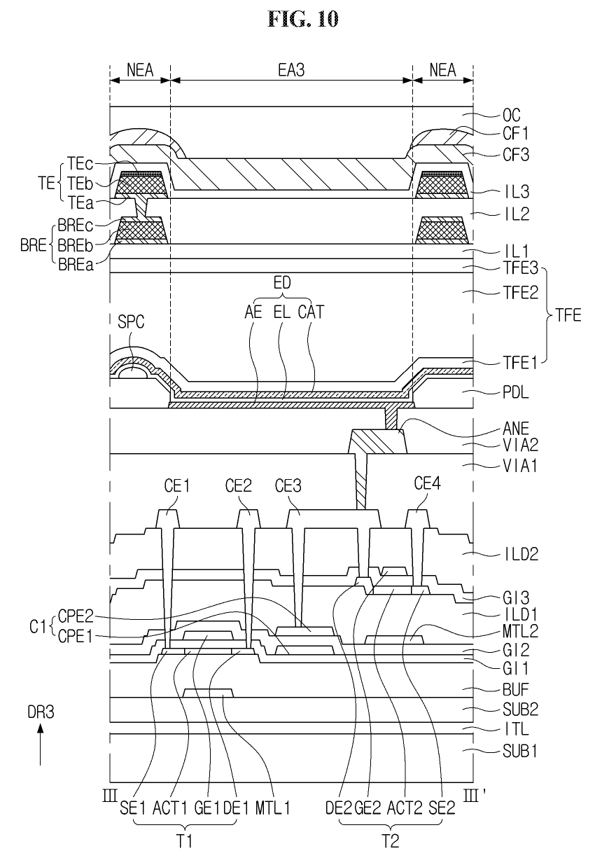

FIG. 8 is a cross-sectional view taken along line I-I’ of FIG. 4, FIG. 9 is a cross-sectional view taken along line II-II’ of FIG. 4. FIG. 10 is a cross-sectional view taken along line III-III’ of FIG. 4.

Referring to FIGS. 8 to 10, the display panel 100 includes a first substrate (SUB1), an intermediate layer (ITL), a second substrate (SUB2), a first light-shielding layer (MTL1), a buffer layer (BUF), a first transistor (T1), a first gate insulating layer (GI1), a first capacitor (C1), a second gate insulating layer (GI2), a second light-shielding layer (MTL2), a first interlayer insulating layer (ILD1), a second transistor (T2), a third gate insulating layer (GI3), a second interlayer insulating layer (ILD2), first to fourth connection electrodes (CE1, CE2, CE3, CE4), a first via layer (VIA1), an anode connection electrode (ANE), a second via layer (VIA2), a pixel defining layer (PDL), a spacer (SPC), a light-emitting element (ED), an encapsulation layer (TFE), a first insulating layer (IL1), a bridge electrode (BRE), a second insulating layer (IL2), a touch electrode (TE), a third insulating layer (IL3), first and third color filters (CF1, CF3), and a planarization layer (OC).

The first substrate (SUB1) can be a base substrate or a base member. The first substrate (SUB1) can be a flexible substrate capable of bending, folding, rolling, etc. For example, the first substrate (SUB1) can include a polymer resin such as polyimide (PI), but is not limited thereto. In another example, the first substrate (SUB1) can include a glass material or a metal material.

The intermediate layer (ITL) can be disposed on the first substrate (SUB1). The intermediate layer (ITL) is disposed between the first and second substrates (SUB1, SUB2) and can include an inorganic insulating material.

The second substrate (SUB2) can be disposed on the intermediate layer (ITL). The second substrate (SUB2) can include the material exemplified in the first substrate (SUB1).

The first light-shielding layer (MTL1) can be disposed on the second substrate (SUB2). The first light-shielding layer (MTL1) can be disposed below the semiconductor region (ACT1) of the first transistor (T1) and can overlap the semiconductor region (ACT1). The first light-shielding layer (MTL1) can prevent light from transmitting into the semiconductor region (ACT1) of the first transistor (T1). The first light-shielding layer (MTL1) can include at least one of molybdenum (Mo), aluminum (Al), chromium (Cr), nickel (Ni), neodymium (Nd), and copper (Cu), but is not limited thereto.

The buffer layer (BUF) can be disposed on the first light-shielding layer (MTL1). For example, the buffer layer (BUF) can include an inorganic layer capable of preventing the penetration of air or moisture. For example, the buffer layer (BUF) can include a plurality of inorganic layers alternately stacked.

The semiconductor region (ACT1), the source electrode (SE1), and the drain electrode (DE1) of the first transistor (T1) can be disposed on the buffer layer (BUF). The semiconductor region (ACT1) of the first transistor (T1) can include a silicon-based material, and the source electrode (SE1) and the drain electrode (DE1) can be formed by being P-type doped. For example, the first active layer (ACTL1) can be formed of low-temperature polycrystalline silicon (LTPS). The source electrode (SE1) of the first transistor (T1) can be connected to the first connection electrode (CE1). The drain electrode (DE1) of the first transistor (T1) can be connected to the second connection electrode (CE2).

The first gate insulating layer (GI1) can be disposed on the semiconductor region (ACT1) of the first transistor (T1). The first gate insulating layer (GI1) can insulate the semiconductor region (ACT1) of the first transistor (T1) from the gate electrode (GE1). The first gate insulating layer (GI1) can include an inorganic material.

The gate electrode (GE1) of the first transistor (T1) and the first capacitor electrode (CPE1) of the first capacitor (C1) can be disposed on a first gate insulating layer (GI1). The gate electrode (GE1) of the first transistor (T1) can overlap the semiconductor region (ACT1) of the first transistor (T1), and the first capacitor electrode (CPE1) of the first capacitor (C1) can overlap the second capacitor electrode (CPE2).

The second gate insulating layer (GI2) can be disposed on the gate electrode (GE1) of the first transistor (T1) and the first capacitor electrode (CPE1). The second gate insulating layer (GI2) can insulate the first and second capacitor electrodes (CPE1, CPE2). The second gate insulating layer (GI2) can include an inorganic material.

The second capacitor electrode (CPE2) and the second light-shielding layer (MTL2) of the first capacitor (C1) can be disposed on the second gate insulating layer (GI2). The second light-shielding layer (MTL2) can be disposed under the semiconductor region (ACT2) of the second transistor (T2) to overlap with the semiconductor region (ACT2). The second light-shielding layer (MTL2) can prevent light from transmitting into the semiconductor region (ACT2) of the second transistor (T2). The second light-shielding layer (MTL2) can include at least one of molybdenum (Mo), aluminum (Al), chromium (Cr), nickel (Ni), neodymium (Nd), and copper (Cu), but is not limited thereto.

The first interlayer insulating layer (ILD1) can be disposed on the second gate insulating layer (GI2). The first interlayer insulating layer (ILD1) can insulate the second light-shielding layer (MTL2) and the semiconductor region (ACT2) of the second transistor (T2). The thickness of the first interlayer insulating layer (ILD1) can be greater than the thickness of the first gate insulating layer (GI1) or the second gate insulating layer (GI2). The first interlayer insulating layer (ILD1) can include an inorganic layer that can prevent the penetration of air or moisture. The first interlayer insulating layer (ILD1) can insulate the first transistor (T1) including a silicon-based material and the second transistor (T2) including an oxide-based material.

The semiconductor region (ACT2), the drain electrode (DE2), and the source electrode (SE2) of the second transistor (T2) can be disposed on the first interlayer insulating layer (ILD1). The semiconductor region (ACT2) of the second transistor (T2) can include an oxide-based material, and the drain electrode (DE2) and the source electrode (SE2) can be formed by N-type doping. The drain electrode (DE2) of the second transistor (T2) can be electrically connected to the second capacitor electrode (CPE2) via the third connection electrode (CE3). The source electrode (SE2) of the second transistor (T2) can be connected to the fourth connection electrode (CE4).

The third gate insulating layer (GI3) can be disposed on the semiconductor region (ACT2) of the second transistor (T2). The third gate insulating layer (GI3) can insulate the semiconductor region (ACT2) and the gate electrode (GE2) of the second transistor (T2).

The gate electrode (GE2) of the second transistor (T2) can be disposed on the third gate insulating layer (GI3). The gate electrode (GE2) of the second transistor (T2) can overlap the semiconductor region (ACT2).

The second interlayer insulating layer (ILD2) can be disposed on the gate electrode (GE2) of the second transistor (T2). The second interlayer insulating layer (ILD2) can insulate the gate electrode (GE2) and the first to fourth connection electrodes (CE1, CE2, CE3, and CE4) of the second transistor (T2). The thickness of the second interlayer insulating layer (ILD2) can be greater than the thickness of the third gate insulating layer (GI3). The second interlayer insulating layer (ILD2) can include an inorganic layer that can prevent the penetration of air or moisture.

The first to fourth connection electrodes (CE1, CE2, CE3, and CE4) can be disposed on the second interlayer insulating layer (ILD2). The first connection electrode (CE1) can be connected to the source electrode (SE1) of the first transistor (T1). The second connection electrode (CE2) can be connected to the drain electrode (DE1) of the first transistor (T1). The third connection electrode (CE3) can electrically connect the drain electrode (DE2) of the second transistor (T2) and the second capacitor electrode (CPE2). The fourth connection electrode (CE4) can be connected to the source electrode (SE2) of the second transistor (T2).

The first via layer (VIA1) can be disposed on the first to fourth connection electrodes (CE1, CE2, CE3, and CE4). The first via layer (VIA1) can insulate the first and second connection electrodes (CE1, CE2) from the anode connection electrode (ANE). The first via layer (VIA1) may also insulate the fourth connection electrode (CE4) from the anode connection electrode (ANE). The top surface of the first via layer (VIA1) can be flat. The first via layer (VIA1) can include an organic insulating material, such as polyimide (PI).

The anode connection electrode (ANE) can be disposed on the first via layer (VIA1). The anode connection electrode (ANE) can electrically connect the third connection electrode (CE3) and the pixel electrode (AE).

The second via layer (VIA2) can be disposed on the anode connection electrode (ANE). The top surface of the second via layer (VIA2) can be flat. The second via layer (VIA2) can include an organic insulating material, such as polyimide (PI).

A pixel defining layer (PDL) can be disposed on the second via layer (VIA2). The pixel defining layer (PDL) can define first to third emission areas (EA1, EA2, EA3). The pixel defining layer (PDL) can include, but is not limited to, an organic material, such as a material including a black pigment, a benzocyclobutene resin, a polyimide resin, an acrylic resin, or a photosensitive polymer. When the pixel defining layer (PDL) includes a material including a black pigment or a black dye, the pixel defining layer (PDL) can be a black bank. By including a black pigment or a black dye, the pixel defining layer (PDL) can block external light and improve the brightness of the display device 10.

A spacer (SPC) can be disposed on the pixel defining layer (PDL). The spacer (SPC) can protrude from the upper surface of the pixel defining layer (PDL) and support the encapsulation layer (TFE). The spacer (SPC) can include the same material as the pixel defining layer (PDL), but is not limited thereto.

The light-emitting element (ED) can include a pixel electrode (AE), an emission layer (EL), and a common electrode (CAT). The pixel electrode (AE) can be disposed on a second via layer (VIA2). The pixel electrode (AE) can overlap one of the first to third emission areas (EA1, EA2, EA3) defined by a pixel defining layer (PDL). The pixel electrode (AE) can be inserted into a contact hole penetrating the second via layer (VIA2) and can be in contact with the anode connection electrode (ANE). The pixel electrode (AE) can receive a driving current from a pixel circuit of the pixel (SP). The pixel electrode (AE) can be a first electrode of the light-emitting element (ED).

The emission layer (EL) can be disposed on the pixel electrode (AE). For example, the emission layer (EL) can be an organic emission layer made of or including an organic material, but is not limited thereto. When the light-emitting layer (EL) corresponds to an organic light-emitting layer, when the pixel circuit of the pixel (SP) applies a predetermined voltage to the pixel electrode (AE), and the common electrode (CAT) receives a common voltage or a cathode voltage, holes can move to the light-emitting layer (EL) through the hole transport layer, electrons can move to the light-emitting layer (EL) through the electron transport layer, and the holes and electrons can combine with each other in the light-emitting layer (EL) to emit light.

The common electrode (CAT) can be disposed on the light-emitting layer (EL). For example, the common electrode (CAT) can be implemented in the form of an electrode common to all pixels (SPs) without being differentiated for each pixel (SP). The common electrode (CAT) can be a transparent electrode and can transmit light. The common electrode (CAT) can be electrically connected to a low-potential line (VSL) and can receive a low-potential voltage, a common voltage, or a cathode voltage. The common electrode (CAT) can be a second electrode of the light-emitting element (ED).

An encapsulation layer (TFE) can be disposed on a light-emitting element (ED). The encapsulation layer (TFE) can be disposed on a common electrode (CAT) to cover a plurality of light-emitting elements (ED). The encapsulation layer (TFE) can include a first encapsulation layer (TFE1), a second encapsulation layer (TFE2), and a third encapsulation layer (TFE3) sequentially stacked on the common electrode (CAT).

The first encapsulation layer (TFE1) can be disposed on the common electrode (CAT). The first encapsulation layer (TFE1) can include an inorganic material to prevent oxygen or moisture from penetrating into the light-emitting element (ED). For example, the first encapsulation layer (TFE1) can include at least one of a silicon nitride layer, a silicon oxynitride layer, a silicon oxide layer, a titanium oxide layer, an aluminum oxide layer, and an amorphous silicon layer, but is not limited thereto.

The second encapsulating layer (TFE2) can be disposed on the first encapsulating layer (TFE1) to planarize the upper surfaces of the plurality of light-emitting elements (ED). The second encapsulating layer (TFE2) can include an organic material to protect the light-emitting elements (ED) from foreign substances such as dust. For example, the second encapsulating layer (TFE2) can include an organic layer such as an acrylic resin, an epoxy resin, a phenolic resin, a polyamide resin, or a polyimide resin. The second encapsulating layer (TFE2) can be formed by curing a monomer or applying a polymer. The embodiments according to the present disclosure are not limited thereto.

The third encapsulating layer (TFE3) can be disposed on the second encapsulating layer (TFE2). The third encapsulating layer (TFE3) can include an inorganic material to prevent oxygen or moisture from penetrating into the light-emitting elements (ED). For example, the third encapsulating layer (TFE3) can include the material exemplified in the first encapsulating layer (TFE1).

The first insulating layer (IL1) can be disposed on the encapsulating layer (TFE). The first insulating layer (IL1) can have insulating and optical functions. The first insulating layer (IL1) can include at least one inorganic layer.

The bridge electrode (BRE) can be disposed in a non-emitting area (NEA) on the first insulating layer (IL1). The bridge electrode (BRE) can be disposed on a different layer from the touch electrode (TE) and can electrically connect the touch electrodes (TE) that are spaced apart from each other. The bridge electrode (BRE) can include first to third layers (BREa, BREb, and BREc).

The first layer (BREa) of the bridge electrode (BRE) can contact the upper surface of the first insulating layer (IL1). The first layer (BREa) of the bridge electrode (BRE) can include a material having strong adhesion to the first insulating layer (IL1). For example, the first layer (BREa) of the bridge electrode (BRE) can include titanium (Ti), thereby allowing easy attachment on the first insulating layer (IL1) including an inorganic layer. However, the constituent material of the first layer (BREa) of the bridge electrode (BRE) is not limited thereto.

The second layer (BREb) of the bridge electrode (BRE) can be disposed on the first layer (BREa). The thickness of the second layer (BREb) of the bridge electrode (BRE) can be greater than the thickness of the first layer (BREa). The thickness of the second layer (BREb) of the bridge electrode (BRE) can be at least ten times the thickness of the first layer (BREa), but is not limited thereto. For example, the second layer (BREb) of the bridge electrode (BRE) can improve conductivity by including aluminum (Al), but the constituent material of the second layer (BREb) of the bridge electrode (BRE) is not limited thereto.

The third layer (BREc) of the bridge electrode (BRE) can be disposed on the second layer (BREb). The thickness of the third layer (BREc) of the bridge electrode (BRE) can be smaller than the thickness of the second layer (BREb). The thickness of the second layer (BREb) of the bridge electrode (BRE) can be ten times or more the thickness of the third layer (BREc), but is not limited thereto. For example, the third layer (BREc) of the bridge electrode (BRE) can include titanium (Ti), but the constituent material of the third layer (BREc) of the bridge electrode (BRE) is not limited thereto.

The second insulating layer (IL2) can be disposed on the bridge electrode (BRE) to planarize the upper end of the bridge electrode (BRE). The second insulating layer (IL2) can insulate the bridge electrode (BRE) and the touch electrode (TE). The second insulating layer (IL2) can include an organic layer. The thickness of the second insulating layer (IL2) can be greater than the thickness of the first insulating layer (IL1).

The touch electrode (TE) can be disposed in the non-emitting area (NEA) on the second insulating layer (IL2). Since the touch electrode (TE) is disposed on the relatively thick second insulating layer (IL2) including the organic layer, the distance from the light emitting element (ED) or the pixel circuit can be increased compared to when the touch electrode (TE) is disposed on a relatively thin inorganic layer. Accordingly, the touch electrode (TE) can prevent a ripple phenomenon or parasitic capacitance and improve touch performance by being disposed on the second insulating layer (IL2). In addition, since the touch electrode (TE) is disposed on the planarized second insulating layer (IL2), it can be easier to control low reflection than when the touch electrode (TE) is disposed on an unplanarized inorganic layer. The display driver (200) can supply a touch driving signal to the touch electrode (TE) and sense the amount of change in electrostatic capacity of the touch electrode (TE). The display driver (200) can calculate whether a touch input has occurred and the touch coordinates based on the amount of change in electrostatic capacity of the touch electrode (TE). The touch electrode (TE) can include first to third layers (TEa, TEb, TEc).

The first layer (TEa) of the touch electrode (TE) can be in contact with the upper surface of the second insulating layer (IL2). The first layer (TEa) of the touch electrode (TE) can include a material having a strong adhesive force with the second insulating layer (IL2). The first layer (TEa) of some of the touch electrodes (TE) can be inserted into a contact hole penetrating the second insulating layer (IL2) and can contact the third layer (BREc) of the bridge electrode (BRE). For example, the first layer (TEa) of the touch electrode (TE) can include titanium (Ti), thereby easily attaching to the second insulating layer (IL2) including an inorganic layer. However, the constituent material of the first layer (TEa) of the touch electrode (TE) is not limited thereto.

The second layer (TEb) of the touch electrode (TE) can be disposed on the first layer (TEa). The thickness of the second layer (TEb) of the touch electrode (TE) can be greater than the thickness of the first layer (TEa). The thickness of the second layer (TEb) of the touch electrode (TE) can be at least ten times the thickness of the first layer (TEa), but is not limited thereto. For example, the second layer (TEb) of the touch electrode (TE) can include aluminum (Al) to enhance conductivity, but the constituent material of the second layer (TEb) of the touch electrode (TE) is not limited thereto.

The third layer (TEc) of the touch electrode (TE) can be disposed on the second layer (TEb). The thickness of the third layer (TEc) of the touch electrode (TE) can be less than the thickness of the second layer (TEb). The thickness of the second layer (TEb) of the touch electrode (TE) can be at least ten times the thickness of the third layer (TEc), but is not limited thereto. The third layer (TEc) of the touch electrode (TE) can include a material having a lower reflectivity than the first layer (TEa). The third layer (TEc) of the touch electrode (TE) can include tungsten oxide (WOx). The third layer (TEc) of the touch electrode (TE) can include an alloy composed of tungsten (W), zinc oxide (ZnO), and yttrium oxide (Y₂O₃). The mixing ratio (Mixing Ratio) of the third layer (TEc) of the touch electrode (TE) can be such that tungsten (W) is the highest, and the percentage concentration or the weight percent (wt%) of tungsten (W) can be 60 to 80. The percentage concentration or the weight percent (wt%) of tungsten (W) can be greater than the sum of the percentage concentrations or the weight percents (wt%) of zinc oxide (ZnO) and yttrium oxide (Y₂O₃). For example, the mixing ratio of tungsten (W), zinc oxide (ZnO), and yttrium oxide (Y₂O₃) can be, but is not limited to, 70:15.5:14.5. The third layer (TEc) of the touch electrode (TE) includes tungsten (W) to reduce the reflectivity of the touch electrode (TE), includes zinc oxide (ZnO) to facilitate wet etching, and includes yttrium oxide (Y₂O₃) to ensure thermal stability. The display device (10) can prevent the recognition of the touch electrode (TE) by including the third layer (TEc) of the touch electrode (TE) having a low-reflection characteristic. According to the various embodiments of the present disclosure, a thickness of the third layer (TEc) of the touch electrode (TE) can be the same or different compared to a thickness of the first layer (TEa) of the touch electrode (TE). According to the various embodiments of the present disclosure, the thickness of the third layer (TEc) of the touch electrode (TE) can be equal to or less than the thickness of the first layer (TEa) of the touch electrode (TE), but is not limited thereto.

The third insulating layer (IL3) can be disposed on the touch electrode (TE). The third insulating layer (IL3) can be disposed between the touch electrode (TE) and the first to third color filters (CF1, CF2, CF3). The thickness of the third insulating layer (IL3) may be smaller than the thickness of the second insulating layer (IL2). The third insulating layer (IL3) can include at least one inorganic layer. The thickness of the touch electrode (TE) can be greater than the thickness of the third insulating layer (IL3). For example, the thickness of the touch electrode (TE) can be 7000 angstroms (Å), and the thickness of the third insulating layer (IL3) can be 2000 angstroms (Å), but is not limited thereto. Accordingly, the first to third color filters (CF1, CF2, CF3) can be disposed on the third insulating layer (IL3), and the height of the lower surface of the first color filter (CF1) disposed in the first emitting area (EA1) based on the second insulating layer (IL2) can be lower than the height of the upper surface of the touch electrode (TE).

The first to third color filters (CF1, CF2, CF3) can be disposed on the third insulating layer (IL3). The first to third color filters (CF1, CF2, CF3) can absorb a portion of light entering from the outside of the display device (10) to reduce reflected light due to external light. Therefore, the first to third color filters (CF1, CF2, CF3) can prevent color distortion due to reflection of external light.

In FIG. 8, the first color filter (CF1) can be directly disposed on the third insulating layer (IL3) in the first emission area (EA1) and directly disposed on the third color filter (CF3) in the non-emission area (NEA). The first color filter (CF1) can overlap with at least one of the touch electrode (TE) and the third color filter (CF3) disposed in the non-emission area (NEA).

In FIG. 9, the second color filter (CF2) can be disposed on the third insulating layer (IL3) in the second emission area (EA2). The second color filter (CF2) need not be disposed in the non-emission area (NEA) and need not overlap with the touch electrode (TE).

In FIG. 10, the third color filter (CF3) can be directly disposed on the third insulating layer (IL3) in the third emission area (EA3) and the non-emission area (NEA). The third color filter (CF3) can overlap the touch electrode (TE) and the first color filter (CF1) arranged in the non-emissive area (NEA). The thickness of the third color filter (CF3) in the non-emissive area (NEA) can be greater than the thickness of the first color filter (CF1) in the non-emissive area (NEA). The thickness of the third color filter (CF3) in the non-emissive area (NEA) can be at least twice the thickness of the first color filter (CF1) in the non-emissive area (NEA), but is not limited thereto. During the manufacturing process of the display device 10, the third color filter (CF3), the second color filter (CF2), and the first color filter (CF1) can be sequentially formed.

Therefore, the first and third color filters (CF1, CF3) can be arranged in the non-emissive area (NEA) and overlap the touch electrode (TE). The display device 10 can prevent the touch electrode (TE) from being viewed without including a separate black matrix by including first and third color filters (CF1, CF3) arranged in a non-emissive area (NEA). In addition, the display device 10 can reduce the number of manufacturing processes and reduce manufacturing costs by not including a separate black matrix.

The planarization layer (OC) can be disposed on the first to third color filters (CF1, CF2, CF3). The planarization layer (OC) can planarize the upper portions of the first to third color filters (CF1, CF2, CF3) and protect the first to third color filters (CF1, CF2, CF3). The planarization layer (OC) can include an organic insulating material.

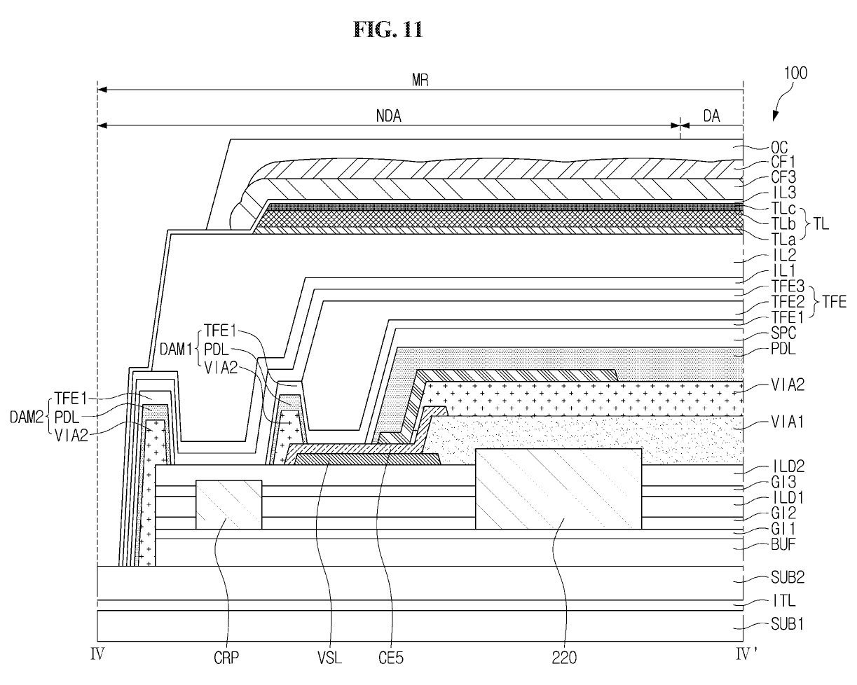

FIG. 11 is a cross-sectional view taken along line IV-IV' of FIG. 4. Hereinafter, configurations identical to the aforementioned configurations will be briefly described or omitted.

Referring to FIG. 11, the display panel 100 can include a first substrate (SUB1), an intermediate layer (ITL), a second substrate (SUB2), a buffer layer (BUF), a first gate insulating layer (GI1), a second gate insulating layer (GI2), a first interlayer insulating layer (ILD1), a third gate insulating layer (GI3), a second interlayer insulating layer (ILD2), a first via layer (VIA1), a second via layer (VIA2), a pixel defining layer (PDL), a spacer (SPC), an encapsulation layer (TFE), a first insulating layer (IL1), a second insulating layer (IL2), a touch line (TL), a third insulating layer (IL3), first and third color filters (CF1, CF3), a planarization layer (OC), a scan driver 220, a low potential line (VSL), a fifth connection electrode (CE5), a crack detection pattern (CRP), a first dam (DAM1), and a second dam (DAM2).

A touch line (TL) can be arranged in a non-display area (NDA) to electrically connect a touch electrode (TE) and a display driver (200). The touch line (TL) can be arranged on a second insulating layer (IL2). The display driver 200 can supply a touch driving signal through the touch line (TL) and sense a change in electrostatic capacity of the touch electrode (TE). The touch line (TL) can include first to third layers (TLa, TLb, and TLc).

The first layer (TLa) of the touch line (TL) can contact an upper surface of the second insulating layer (IL2). The first layer (TLa) of the touch line (TL) can include a material having strong adhesiveness with the second insulating layer (IL2). For example, the first layer (TLa) of the touch line (TL) can be easily attached to the second insulating layer (IL2) including an inorganic layer by including titanium (Ti), but the constituent material of the first layer (TLa) of the touch line (TL) is not limited thereto.

The second layer (TLb) of the touch line (TL) can be disposed on the first layer (TLa). The thickness of the second layer (TLb) of the touch line (TL) can be greater than the thickness of the first layer (TLa). The thickness of the second layer (TLb) of the touch line (TL) can be at least ten times the thickness of the first layer (TLa), but is not limited thereto. For example, the second layer (TLb) of the touch line (TL) can be improved in conductivity by including aluminum (Al), but the constituent material of the second layer (TLb) of the touch line (TL) is not limited thereto.

The third layer (TLc) of the touch line (TL) can be disposed on the second layer (TLb). The thickness of the third layer (TLc) of the touch line (TL) can be smaller than the thickness of the second layer (TLb). The thickness of the second layer (TLb) of the touch line (TL) can be ten times or more the thickness of the third layer (TLc), but is not limited thereto. The third layer (TLc) of the touch line (TL) can include a material having a lower reflectivity than the first layer (TLa). The third layer (TLc) of the touch line (TL) can include tungsten oxide (WOx). The third layer (TLc) of the touch line (TL) can include an alloy composed of tungsten (W), zinc oxide (ZnO), and yttrium oxide (Y₂O₃). The mixing ratio of the third layer (TLc) of the touch line (TL) can be highest in tungsten (W), and the percentage concentration or the weight percent (wt%) of tungsten (W) can be 60 to 80. The percentage concentration or the weight percent (wt%) of tungsten (W) can be greater than the sum of the percentage concentrations or the weight percents (wt%) of zinc oxide (ZnO) and yttrium oxide (Y₂O₃). For example, the mixing ratio of tungsten (W), zinc oxide (ZnO), and yttrium oxide (Y₂O₃) can be, but is not limited to, 70:15.5:14.5. The third layer (TLc) of the touch line (TL) includes tungsten (W) to reduce the reflectivity of the touch line (TL), zinc oxide (ZnO) to facilitate wet etching, and yttrium oxide (Y₂O₃) to ensure thermal stability. The display device (10) can prevent the touch line (TL) from being viewed by including the third layer (TLc) of the touch line (TL) with low-reflection characteristics.

The third insulating layer (IL3) may be disposed on the touch line (TL). The third color filter (CF3) can be directly disposed on the third insulating layer (IL3), and the first color filter (CF1) can be directly disposed on the third color filter (CF3). The first and third color filters (CF1, CF3) can be disposed in the non-display area (NDA) to overlap the touch line (TL). For example, the first and third color filters (CF1, CF3) can cover the ends of the touch line (TL). The thickness of the third color filter (CF3) in the non-display area (NDA) can be at least twice the thickness of the first color filter (CF1), but is not limited thereto. The display device (10) can prevent the touch line (TL) from being viewed without including a separate black matrix by including the first and third color filters (CF1, CF3) arranged in the non-display area (NDA). In addition, the display device 10 can reduce the number of manufacturing processes and reduce manufacturing costs by not including a separate black matrix.

Referring to FIG. 1, the scan driver 220 can be arranged in the non-display area (NDA). The scan driver 220 can include a plurality of transistors and supply scan signals to a plurality of pixels (SP). The scan signals of the scan driver 220 can select pixels (SP) to which data voltages are supplied, and the selected pixels (SP) can receive the data voltages through data lines. The scan driver 220 can be arranged in a GIP (Gate In Panel) manner.

A low-potential line (VSL) can be arranged in a non-display area (NDA) to surround the scan driver 220 and the display area (DA). The low-potential line (VSL) can supply a low-potential voltage to the display area (DA) through a fifth connection electrode (CE5). The low-potential line (VSL) can be arranged on a second interlayer insulating layer (ILD2), and the fifth connection electrode (CE5) can be arranged on a first via layer (VIA1).

A crack detection pattern (CRP) can surround the low-potential line (VSL), the scan driver (220), and the display area (DA). The crack detection pattern (CRP) can completely surround the display area (DA). A crack detection pattern (CRP) can be positioned between the first dam (DAM1) and the second dam (DAM2). When an external impact is applied to the display device (10), the crack detection pattern (CRP) can be damaged, and a damaged crack detection pattern (CRP) can indicate that a crack has occurred in the display device 10. The crack detection pattern (CRP) can be formed as a gate electrode, a source electrode, or a drain electrode of a transistor.

The first dam (DAM1) can be formed by stacking a second via layer (VIA2), a pixel defining layer (PDL), and a first encapsulating layer (TFE1). The first dam (DAM1) can surround a low potential line (VSL) and cover one end of a fifth connection electrode (CE5). The first dam (DAM1) can protrude above the second interlayer insulating layer (ILD2) to prevent the second encapsulating layer (TFE2) from overflowing.

The second dam (DAM2) can be formed by stacking a second via layer (VIA2), a pixel defining layer (PDL), and a first encapsulating layer (TFE1). The second dam (DAM2) can surround a crack detection pattern (CRP). The second dam (DAM2) can protrude over the second substrate (SUB2) to prevent the second insulating layer (IL2) from overflowing.

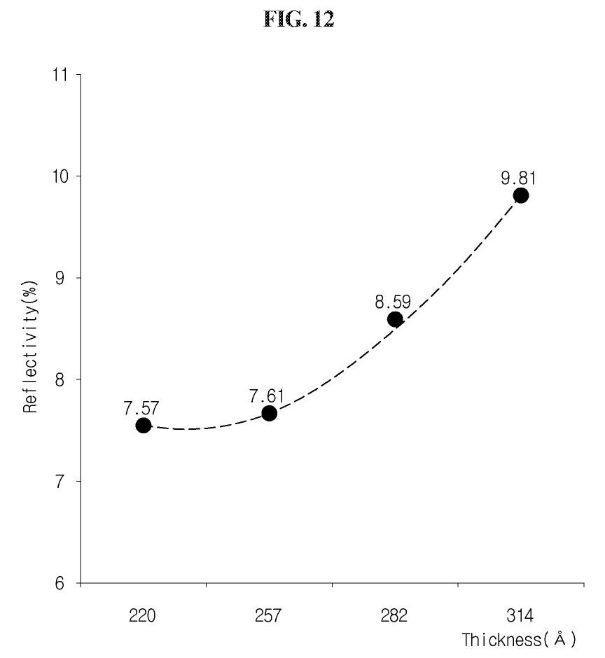

FIG. 12 is a graph showing reflectance based on the thickness of a low-reflection metal in a display device according to one embodiment according to the present disclosure.

Referring to FIG. 12 , the low-reflection metal can include tungsten oxide (WOx). For example, the low-reflection metal can include an alloy composed of tungsten (W), zinc oxide (ZnO), and yttrium oxide (Y₂O₃). Therefore, the graph of FIG. 12 shows reflectance according to the thickness of the third layer (TEc) of the touch electrode (TE) and the third layer (TLc) of the touch line (TL).

When the thickness of the low-reflection metal is 220 angstroms (Å), it can have a reflectivity of 7.57, and when the thickness of the low-reflection metal is 257 angstroms (Å), it can have a reflectivity of 7.61. When the thickness of the low-reflection metal is 282 angstroms (Å), it can have a reflectivity of 8.59, and when the thickness of the low-reflection metal is 314 angstroms (Å), it can have a reflectivity of 9.81. The third layer (TEc) of the touch electrode (TE) or the third layer (TLc) of the touch line (TL) can have a relatively lower reflectivity than when it includes titanium (Ti) by including a low-reflection metal composed of tungsten (W), zinc oxide (ZnO), and yttrium oxide (Y₂O₃). Accordingly, the display device (10) can have a lower reflectivity and improve visibility by including a touch electrode (TE) composed of WOx/Al/Ti than an electrode composed of Ti/Al/Ti. As provided in FIG. 12, a reflectivity of the third layer (TEc) of the touch electrode (TE) or the third layer (TLc) of the touch line (TL) can increase with increasing thickness, but a rate of the increase need not be linear. In various embodiments according to present disclosure, the increase can be exponential, but is not limited thereto.

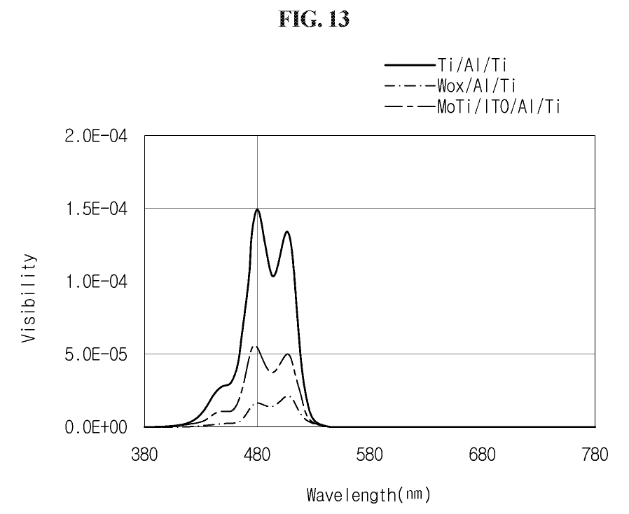

FIG. 13 is a graph showing the visibility of a low-reflection metal overlapping the first and third color filters according to the wavelength in a display device according to one embodiment according to the present disclosure.

Referring to FIG. 13, the first metal (Ti/Al/Ti) can be formed by sequentially stacking titanium (Ti), aluminum (Al), and titanium (Ti). The first metal (Ti/Al/Ti) can have a visibility of about 1.5E-04 at a wavelength of about 480 nm and a visibility of about 1.3E-0.4 at a wavelength of about 500 nm. The second metal (WOx/Al/Ti) can be formed by sequentially stacking titanium (Ti), aluminum (Al), and tungsten oxide (WOx). Here, the second metal (WOx/Al/Ti) can correspond to a touch electrode (TE) or a touch line (TL) of the display device 10. The second metal (WOx/Al/Ti) can have a visibility of about 1.5E-05 at a wavelength of about 480 nm and a visibility of about 2.0E-0.5 at a wavelength of about 500 nm. The third metal (MoTi/ITO/Al/Ti) can be formed by sequentially stacking titanium (Ti), aluminum (Al), indium tin oxide (ITO), and molybdenum titanium (MoTi). The third metal (MoTi/ITO/Al/Ti) can have a visibility of about 5.5E-0.5 at a wavelength of about 480 nm and a visibility of about 5.0E-05 at a wavelength of about 500 nm.

Therefore, the display device 10 can prevent visibility of the touch electrode (TE) or touch line (TL) compared to other metals by including a touch electrode (TE) or touch line (TL) made of the second metal (WOx/Al/Ti).

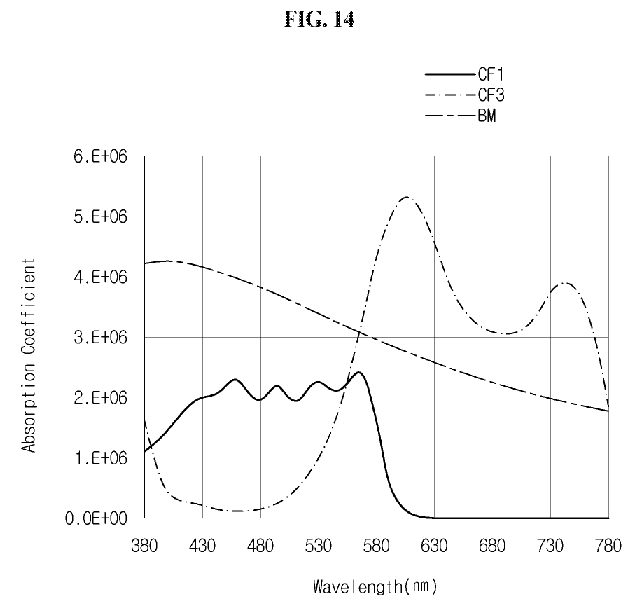

FIG. 14 is a graph showing absorption coefficients of the black matrix and the first and third color filters according to wavelength in a display device according to one embodiment according to the present disclosure.

Referring to FIG. 14, the black matrix (BM) can have an absorption coefficient of about 4.2E+06 at a wavelength of about 380 nm and an absorption coefficient of about 1.8E+06 at a wavelength of about 780 nm. The absorption coefficient of the black matrix (BM) can decrease from a wavelength of 380 nm to a wavelength of 780 nm.

The third color filter (CF3) can have a greater absorption coefficient than the black matrix (BM) at a wavelength of about 560 nm or more. The third color filter (CF3) can have an absorption coefficient of about 5.2E+06 at a wavelength of about 600 nm and an absorption coefficient of about 3.9E+06 at a wavelength of about 740 nm. Therefore, the third color filter (CF3) can absorb light at a wavelength of about 560 nm or more better than the black matrix (BM).

The first color filter (CF1) can have an absorption coefficient of 2.0E+0.6 or greater at a wavelength of about 430 nm to about 570 nm. Therefore, the display device (10) can prevent the visibility of the touch electrode (TE) and the touch line (TL) without including a separate black matrix by including the first and third color filters (CF1, CF3) arranged in the non-emission area (NEA) and the non-display area (NDA). In addition, the display device (10) can reduce the number of manufacturing processes and lower manufacturing costs by not including a separate black matrix (BM).

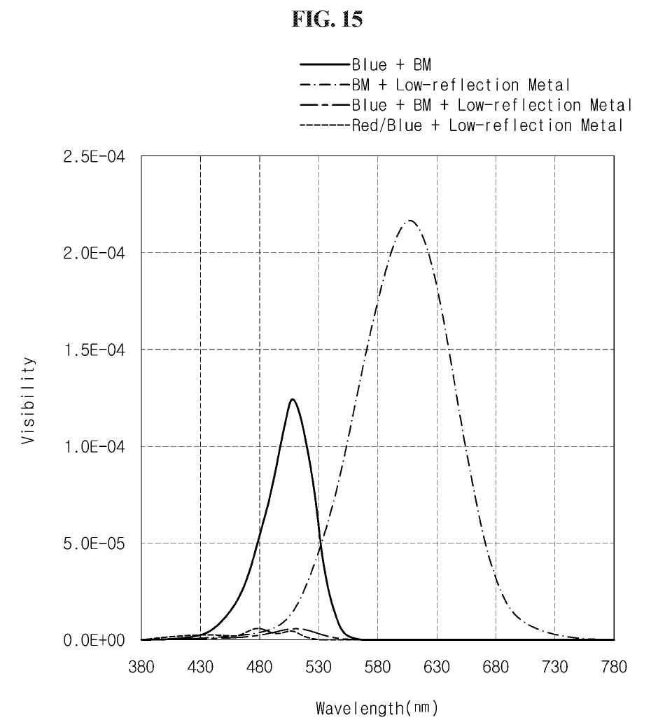

FIG. 15 is a graph showing visibility according to wavelength by combining a color filter, a black matrix, and a low-reflection metal in a display device according to one embodiment according to the present disclosure. Here, the low-reflection metal can include tungsten oxide (WOx).

Referring to FIG. 15, the first stacked structure (Blue+BM) can include a third color filter (CF3) and a black matrix (BM), and the second stacked structure (BM+low-reflective metal) can include a black matrix (BM) and tungsten oxide (WOx). The third stacked structure (Blue+BM+low-reflective metal) can include a third color filter (CF3), a black matrix (BM), and tungsten oxide (WOx), and the fourth stacked structure (Red/Blue+low-reflective metal) can include first and third color filters (CF1, CF3) and tungsten oxide (WOx). The fourth stacked structure (Red/Blue+low-reflective metal) can correspond to a combination of the first and third color filters (CF1, CF3), a touch electrode (TE), and a touch line (TL) of the display device 10.

The first stacked structure (Blue + BM) can improve visibility at a wavelength of about 550 nm or more, but can deteriorate visibility at a wavelength of about 500 nm. The second stacked structure (BM + low-reflection metal) can deteriorate visibility at a wavelength of about 530 nm to about 680 nm. Since the second stacked structure (BM + low-reflection metal) does not include a third color filter (CF3), it can be difficult to block long wavelengths in the visible range. The third stacked structure (Blue + BM + low-reflection metal) and the fourth stacked structure (Red/Blue + low-reflection metal) can improve visibility in all visible ranges. Therefore, the display device 10 can prevent visibility of the touch electrode (TE) and the touch line (TL) without including a separate black matrix by including the fourth stacked structure (Red/Blue + low-reflection metal). In addition, since the display device 10 does not include a separate black matrix, the number of manufacturing processes can be reduced and manufacturing costs can be reduced.

The display device 10 according to various embodiments of the present disclosure can be described as follows.

The display device according to the various embodiments of the present disclosure can include a display area comprising a first emitting area, a second emitting area and a third emitting area configured to emit light of first color, second color and third color, respectively, and non-emitting areas surrounding each of the first emitting area, the second emitting area and the third emitting area; a non-display area disposed around the display area; a first color filter disposed in the first emitting area, the non-emitting area, and the non-display area; a second color filter disposed in the second emitting area; a third color filter disposed in the third emitting area, the non-emitting area, and the non-display area; and a touch electrode disposed in the non-emitting area, and the touch electrode can include a first layer comprising a first material; a second layer disposed on the first layer; and a third layer disposed on the second layer and comprising a second material having a lower reflectivity than the first material.

The display device according to the various embodiments of the present disclosure can further comprise an insulating layer disposed on the touch electrode, and the third color filter can be directly disposed on the insulating layer in the non-emitting area.

In the display device according to the various embodiments of the present disclosure, the first color filter can be directly disposed on the third color filter in the non-emitting area.

In the display device according to the various embodiments of the present disclosure, the thickness of the third color filter in the non-emitting area can be at least twice the thickness of the first color filter.

In the display device according to the various embodiments of the present disclosure, the third layer of the touch electrode can include tungsten oxide (WOx).

In the display device according to the various embodiments of the present disclosure, the first layer of the touch electrode can include titanium (Ti), the second layer of the touch electrode can include aluminum (Al), and the third layer of the touch electrode includes an alloy composed of tungsten (W), zinc oxide (ZnO), and yttrium oxide (Y₂O₃).

In the display device according to the various embodiments of the present disclosure, the percentage concentration of tungsten in the third layer of the touch electrode can 60 to 80.

In the display device according to the various embodiments of the present disclosure, in the third layer of the touch electrode, the percentage concentration of the tungsten can be greater than the sum of the percentage concentrations of the zinc oxide (ZnO) and yttrium oxide (Y₂O₃).

The display device according to the various embodiments of the present disclosure can further comprise a touch line disposed in the non-display area and electrically connected to the touch electrode, and the first color filter and the third color filter can overlap with the touch line.

In the display device according to the various embodiments of the present disclosure, the thickness of the third color filter in the non-display area can be at least twice the thickness of the first color filter.

In the display device according to the various embodiments of the present disclosure, the touch line can include a first layer comprising titanium (Ti); a second layer disposed on the first layer and comprising aluminum (Al); and a third layer disposed on the second layer and comprising an alloy composed of tungsten (W), zinc oxide (ZnO), and yttrium oxide (Y₂O₃).

In the display device according to the various embodiments of the present disclosure, the percentage concentration of tungsten in the third layer of the touch line can be 60 to 80.

In another aspect, a display device according to the various embodiments of the present disclosure can include a display area including a first emitting area, a second emitting area and a third emitting area configured to emit light of first color, second color and third color, respectively, and non-emitting areas surrounding each of the first emitting area, the second emitting area and the third emitting area; a non-display area disposed around the display area; a touch electrode disposed in the non-emitting area; a touch line disposed in the non-display area and electrically connected to the touch electrode; a first color filter disposed in the first emitting area, the non-emitting area, and the non-display area, to overlap the touch electrode and the touch line; a second color filter disposed in the second emitting area; and a third color filter disposed in the third emitting area, the non-emitting area, and the non-display area, to overlap the touch electrode and the touch line.

the display device according to the various embodiments of the present disclosure can further comprise a first insulating layer disposed on the touch electrode and the touch line, and the third color filter can be directly disposed on the first insulating layer in the non-emitting area and the non-display area.

In the display device according to the various embodiments of the present disclosure, the first color filter can be directly disposed on the third color filter in the non-emitting area and the non-display area.

In the display device according to the various embodiments of the present disclosure, the thickness of the third color filter in the non-emitting area and the non-display area can be at least twice the thickness of the first color filter.

In the display device according to the various embodiments of the present disclosure, each of the touch electrode and the touch line can include a first layer comprising titanium (Ti); a second layer disposed on the first layer and comprising aluminum (Al); and a third layer disposed on the second layer and comprising an alloy composed of tungsten (W), zinc oxide (ZnO), and yttrium oxide (Y₂O₃).

The display device according to the various embodiments of the present disclosure can further comprise a bridge electrode disposed below the touch electrode to be electrically connected to the touch electrode, and the bridge electrode can include a first layer comprising titanium (Ti); a second layer disposed on the first layer and comprising aluminum (Al); and a third layer disposed on the second layer and comprising titanium (Ti).

The display device according to the various embodiments of the present disclosure can further comprise a second insulating layer disposed between the bridge electrode and the touch electrode and comprising an organic layer configured to planarize the upper end of the bridge electrode.

Although the present invention has been described with reference to the exemplified drawings, it is to be understood that the present invention is not limited to the embodiments and drawings disclosed in this disclosure, and those skilled in the art will appreciate that various modifications are possible without departing from the scope and spirit of the present invention. Further, although the operating effects according to the configuration of the present invention are not explicitly described while describing an embodiment of the present disclosure, it should be appreciated that predictable effects are also to be recognized by the configuration.

What is claimed is:

1. A display device comprising:
a display area comprising a first emitting area, a second emitting area and a third emitting area configured to emit light of first to third colors, respectively, and a non-emitting area adjacent to each of the first emitting area, the second emitting area and the third emitting area;
a non-display area disposed around the display area;
a first color filter disposed in the first emitting area, the non-emitting area, and the non-display area;
a second color filter disposed in the second emitting area;
a third color filter disposed in the third emitting area, the non-emitting area, and the non-display area; and
a touch electrode disposed in the non-emitting area,
wherein the touch electrode comprises:
a first layer comprising a first material;
a second layer disposed on the first layer; and
a third layer disposed on the second layer and comprising a second material having a lower reflectivity than the first material.

2. The display device of claim 1, further comprising an insulating layer disposed on the touch electrode,
wherein the third color filter is directly disposed on the insulating layer in the non-emitting area.

3. The display device of claim 2, wherein the first color filter is directly disposed on the third color filter in the non-emitting area.

4. The display device of claim 1, wherein a thickness of the third color filter in the non-emitting area is at least twice a thickness of the first color filter in the non-emitting area.

5. The display device of claim 1, wherein the third layer of the touch electrode comprises tungsten oxide (WOx).

6. The display device of claim 1, wherein the first layer of the touch electrode includes titanium (Ti), the second layer of the touch electrode includes aluminum (Al), and the third layer of the touch electrode includes an alloy composed of tungsten (W), zinc oxide (ZnO), and yttrium oxide (Y₂O₃).

7. The display device of claim 6, wherein a weight percent of tungsten in the third layer of the touch electrode is 60 to 80.

8. The display device of claim 6, wherein in the third layer of the touch electrode, weight percent of the tungsten is greater than a sum of a weight percent of the zinc oxide (ZnO) and yttrium oxide (Y₂O₃).

9. The display device of claim 1, further comprising a touch line disposed in the non-display area and electrically connected to the touch electrode,
wherein the first color filter and the third color filter overlap with the touch line.

10. The display device of claim 9, further comprising an insulating layer disposed on the touch line,
wherein the third color filter is directly disposed on the insulating layer in the non-display area, and the first color filter is directly disposed on the third color filter.

11. The display device of claim 9, wherein a thickness of the third color filter in the non-display area is at least twice a thickness of the first color filter in the non-display area.

12. The display device of claim 9, wherein the touch line comprises:
a first layer including titanium (Ti);
a second layer disposed on the first layer and including aluminum (Al); and
a third layer disposed on the second layer and including an alloy composed of tungsten (W), zinc oxide (ZnO), and yttrium oxide (Y₂O₃12).

13. The display device of claim 12, wherein a weight percent of tungsten in the third layer of the touch line is 60 to 80.

14. The display device of claim 1, wherein the second color filter is disposed only in the second emitting area.

15. A display device comprising:
a display area comprising a first emitting area, a second emitting area and a third emitting area configured to emit light of first to third colors, respectively, and a non-emitting area surrounding each of the first emitting area, the second emitting area and the third emitting area;
a non-display area disposed around the display area;
a touch electrode disposed in the non-emitting area;
a touch line disposed in the non-display area and electrically connected to the touch electrode;
a first color filter disposed in the first emitting area, the non-emitting area, and the non-display area, to overlap the touch electrode and the touch line;
a second color filter disposed in the second emitting area; and
a third color filter disposed in the third emitting area, the non-emitting area, and the non-display area, and overlapping the touch electrode and the touch line.

16. The display device of claim 15, further comprising a first insulating layer disposed on the touch electrode and the touch line,
wherein the third color filter is directly disposed on the first insulating layer in the non-emitting area and the non-display area.

17. The display device of claim 16, wherein the first color filter is directly disposed on the third color filter in the non-emitting area and the non-display area.

18. The display device of claim 15, wherein a thickness of the third color filter in the non-emitting area and the non-display area is at least twice a thickness of the first color filter in the non-emitting area and the non-display area.

19. The display device of claim 15, wherein each of the touch electrode and the touch line comprises:
a first layer including titanium (Ti);
a second layer disposed on the first layer and including aluminum (Al); and
a third layer disposed on the second layer and including an alloy composed of tungsten (W), zinc oxide (ZnO), and yttrium oxide (Y₂O₃19).

20. The display device of claim 19, further comprising a bridge electrode disposed below the touch electrode to be electrically connected to the touch electrode,
wherein the bridge electrode comprises:
a first layer including titanium (Ti);
a second layer disposed on the first layer and including aluminum (Al); and
a third layer disposed on the second layer and including titanium (Ti).

21. The display device of claim 20, further comprising a second insulating layer disposed between the bridge electrode and the touch electrode and including an organic layer configured to planarize an upper end of the bridge electrode.

22. The display device of claim 15, wherein the second color filter is disposed only in the second emitting area.

23. A display device comprising:
a display area comprising a plurality of emitting areas configured to emit light of different colors, respectively, and a non-emitting area adjacent to the plurality of emitting areas;
a non-display area disposed adjacent to the display area; and
a plurality of color filters respectively corresponding to the different colors,
wherein at least two of the plurality of color filters overlap each other in at least one of the non-emitting area and the non-display area.

24. The display device of claim 23, wherein one of the plurality of color filters is not disposed in the non-emitting area and the non-display area, and does not overlap the at least two of the plurality of color filters that are overlapping each other in the at least one of the non-emitting area and the non-display area.

25. The display device of claim 23, wherein the at least two of the plurality of color filters are a red color filter and a blue color filter, and the one of the plurality of color filters is a green color filter, and
wherein a thickness of the blue color filter is greater than a thickness of the red color filter.

26. The display device of claim 23, further comprising:
a touch electrode disposed in the non-emitting area; and
a touch line disposed in the non-display area and electrically connected to the touch electrode,
wherein the at least two of the plurality of color filters further overlap at least one of the touch electrode and the touch line.

27. The display device of claim 26, wherein the touch electrode comprises:
one layer comprising a first material; and
another layer disposed on the one layer and comprising a second material having a lower reflectivity than the first material.

28. The display device of claim 27, wherein a thickness of the another layer is equal to or less than a thickness of the one layer.
